(19) United States
(12) Patent Application Publication
(10) Pub. No.: US 2009/0091027 A1
(43) Pub. Date: Apr. 9, 2009

(54) Semiconductor package having restraining ring surfaces against soldering crack

(75) Inventor: Wen-Jeng Fan, Hsinchu (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/905,947

(22) Filed: Oct. 5, 2007

(51) Int. Cl. H01L 23/48

(52) U.S. Cl. 257/737; 257/E23.021

(57) ABSTRACT

A semiconductor package with crack-restraining ring surfaces is revealed, primarily comprising a chip carrier, a chip disposed on the chip carrier, and a plurality of belfry-like bumps. The belfry-like bumps are disposed on a plurality of corresponding conductive pads on the bottom surface of the chip carrier as external terminals. Each belfry-like bump has at least a crack-restraining ring surface parallel to the conductive pads and between the top of the belfry-like bump and the conductive pad to prevent the spreading of the soldering cracks and to enhance the soldering strengths at the micro contacts to achieve higher package reliability.

### FIELD OF THE INVENTION

The present invention relates to 3D (three-dimensional) stacking technologies of semiconductor packages, especially to a semiconductor package with crack-restraining ring surfaces which can be implemented in 3D packaging of Package-On-Package device (POP).

### BACKGROUND OF THE INVENTION

As the electronic products become smaller and smaller, the available surfaces of printed circuit boards for mounting semiconductor packages become smaller and smaller as well. Therefore, 3D stacking technologies of semiconductor packages were developed to vertically stack a plurality of semiconductor packages to become a Package-On-Package device (POP), to meet the requirements of smaller footprints with higher density of components. However, soldering defects become a serious issue during package stacking, moreover, the soldering interfaces between fine-pitch terminals are even vulnerable to stresses causing broken electrical connections and leading to electrical open.

Two known micro contact structures with pillars bumps or needle bumps for package stacking with solder paste had been revealed in U.S. Pat. No. 6,476,503 by Fujitsu and in US patent publication No. 2006/0138647 by Tessera.

As shown in FIG. 1, a conventional semiconductor package 100 primarily comprises a chip carrier 110, a chip 120, and a plurality of pillar bumps 130 where the chip carrier 110 has a top surface 111 and a bottom surface 112. A plurality of first conductive pads 113 are disposed on the bottom surface 112 and a plurality of second conductive pads 114 on the top surface 111. The chip 120 is disposed on the chip carrier 110 and is electrically connected to the chip carrier 110 with a plurality of bonding wires 121 passing through a wire-bonding slot 115 where the bonding wires 121 are encapsulated by an encapsulant 140. The pillar bumps 130 are disposed on the corresponding first conductive pads 113. The pillar bumps 130 disposed beneath one package 100 are electrically connected to the second conductive pads 114 on another semiconductor package 100 stacked below by the solder paste 150 to achieve micro contacts and higher pin counts, to increase available routing areas, and to shrink the POP stacking standoffs.

However, the above mentioned micro contacts become sensitive to external stresses because the inclined sidewalls 131 of the pillar bumps 130 continuously extend to the first conductive pads 113. When the external stresses are exerted on the soldering interfaces of the pillar bumps 130, soldering cracks will occur and spread along the inclined sidewalls 131 of the pillar bumps 130 leading to electrical open.

### SUMMARY OF THE INVENTION

The main purpose of the present invention is to provide a semiconductor package with crack-restraining ring surfaces where the external terminals of the chip carrier are belfry-like bumps having at least a crack-restraining ring surface to avoid cracks occurring and spreading along the soldering interfaces and to prevent electrical open. Moreover, the solderability can be enhanced and the higher product reliability can be achieved.

The second purpose of the present invention is to provide a semiconductor package with crack-restraining ring surfaces to reduce the spreading of soldering cracks of the micro contacts, especially for Package-On-Package (POP).

According to the present invention, a semiconductor package with crack-restraining ring surfaces primarily comprises a chip carrier, a chip, and a plurality of belfry-like bumps. The chip carrier has a top surface and a bottom surface where a plurality of first conductive pads are disposed on the bottom surface. The chip is disposed on and electrically connected to the chip carrier. The belfry-like bumps are disposed on the corresponding first conductive pads as external terminals. Each belfry-like bump has at least a first crack-restraining ring surface parallel to the first conductive pad and between the top of the belfry-like bump and the first conductive pad for preventing the spreading of the soldering cracks.

### DESCRIPTION OF THE DRAWINGS

FIG. 1 shows a cross-sectional view of a plurality of conventional stacked semiconductor packages.

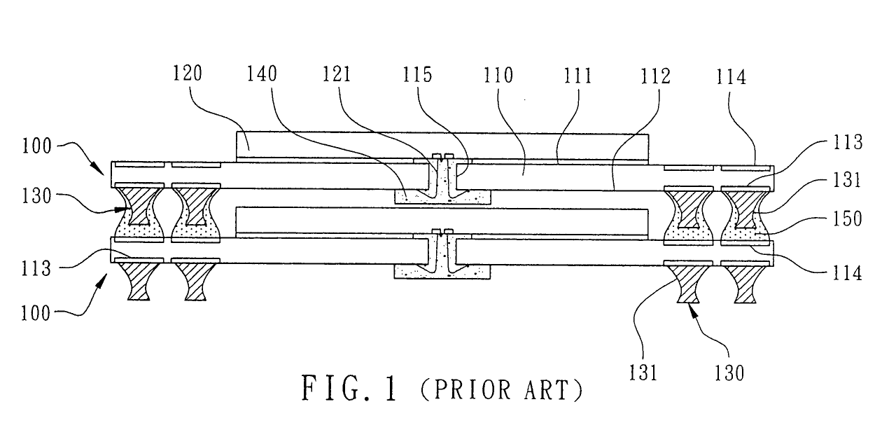

FIG. 2 shows a cross-sectional view of a plurality of semiconductor packages stacked together according to the first embodiment of the present invention.

FIG. 3 shows a 3D view of one belfry-like bump of the semiconductor package according to the first embodiment of the present invention.

FIG. 4 shows a cross-sectional view of a plurality of semiconductor packages stacked and mounted on a printed circuit board according to the second embodiment of the present invention.

FIG. 5 shows a 3D view of another belfry-like bump for the semiconductor package according to the second embodiment of the present invention.

### DETAIL DESCRIPTION OF THE INVENTION

Please refer to the attached drawings, the present invention will be described by means of embodiment(s) below.

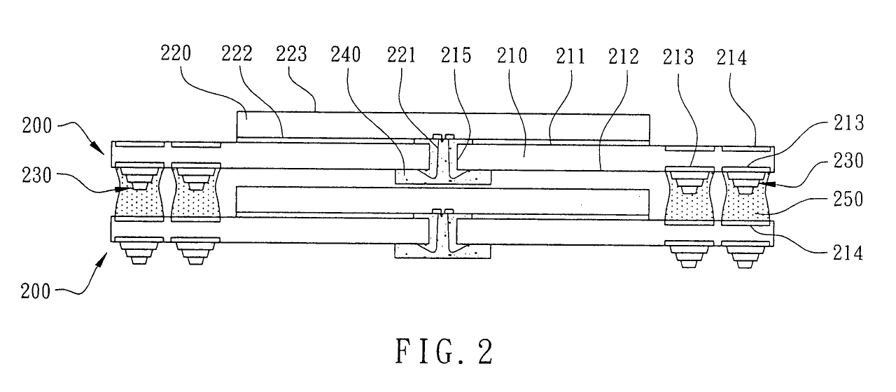

According to the first embodiment of the present invention a semiconductor package with crack-restraining ring surfaces is revealed. Two stacked semiconductor packages 200 are shown in FIG. 2 which more than two semiconductor packages 200 can be stacked, such as three, four, or more. Each semiconductor package 200 primarily comprises a chip carrier 210, a chip 220, and a plurality of belfry-like bumps 230 where the chip carrier 210 is a single layer, double layer, or multi-layer printed circuit board. The chip carrier 210 has a top surface 211 and a bottom surface 212 where a plurality of first conductive pads 213 are disposed on the bottom surface 212 as external terminals for the chip carrier 210. In the present embodiment, the semiconductor package 200 can be implemented in POP (Package-On-Package) applications. A plurality of second conductive pads 214 are disposed on the top surface 211 as the stacking pads for the chip carrier 210 for electrical connections and mechanical placement of another semiconductor package 200.

The chip 200 is disposed on and electrically connected to the chip carrier 210, for example, the active surface 222 of the chip 220 is attached to the top surface 211 of the chip carrier 210 by a die-attaching material, then is electrically connected to the inner fingers of the chip carrier 210 by a plurality of bonding wires 221. In the present embodiment, the chip carrier 210 has a wire-bonding slot 215 through the top surface 211 and bottom surface 212. The bonding wires 221 are electrically connected the chip 220 to the chip carrier 210 by passing through the wire-bonding slot 215. In different embodiment, the chip 220 is electrically connected to the chip carrier 210 by flip-chip bonding, not shown in the figure.

In the present embodiment, the semiconductor package 200 further comprises an encapsulant 240 formed in the wire-bonding slot 215 and extruding from the bottom surface 212 by molding or dispensing to encapsulate the bonding wires 221. The encapsulant 240 does not encapsulate the chip 220 to expose the back surface 223 of the chip 220 and the second conductive pads 214 from the top surface 211 of the chip carrier 210 for heat dissipation and for thinner packages.

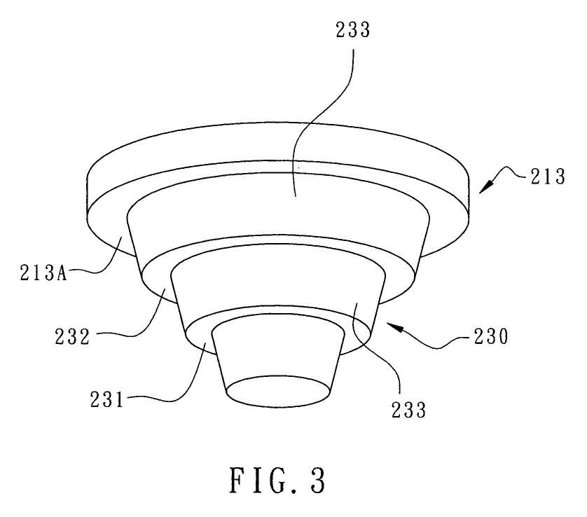

The belfry-like bumps 230 are disposed on the corresponding first conductive pads 213 where each belfry-like bump 230 is aligned with a corresponding first conductive pad 213 for external connections. As shown in FIG. 3, the belfry-like bumps 230 have multi-layer structure where each belfry-like bump 230 has at least a first crack-restraining ring surface 231 parallel to the first conductive pad 213 and between the top of the belfry-like bump 230 and the first conductive pad 213. Therefore, each belfry-like bump 230 has a plurality of non-continuous sidewalls 233. The non-continuous sidewalls 233 are connected to the top edge and the bottom edge of the first crack-restraining ring surface 231 with acute or right angles to form a crack-restraining step so that the first restraining ring surface 231 can prevent the spreading of the soldering cracks. In the present embodiment, the first conductive pad 213 has a peripheral surface 213A exposed from the bottom of the belfry-like bumps 230 and covered by a substrate solder mask (not shown in figures) or soldered by the solder paste 250. As shown in FIG. 3 again, each belfry-like bump 230 further has a second crack-restraining ring surface 232 formed between the first crack-restraining ring surface 231 and the corresponding first conductive pad 213 and parallel to the first crack-restraining ring surface 231 without intersection. Moreover, the inner diameter of the second crack-restraining ring surface 232 is larger than the one of the first crack-restraining ring surface 231 to form a plurality of non-continuous sidewalls 233.

To be more specific, the semiconductor package 200 further comprises a solder paste 250 to solder the belfry-like bumps 230 on the corresponding first conductive pads 213 of one semiconductor package 200 stacked above to the second conductive pads 214 of another semiconductor package 200 stacked below to achieve POP. Preferably, the solder paste 250 can further solder to the peripheral surface 213A so that the whole belfry-like bumps 230 are soldering by the solder paste 250. Normally the solder paste 250 is lead-free solder such as 96.5% of tin, 3% of silver, and 0.5% of copper with reflow temperature above 217° C. where the soldering wettability will be at the maximum reflow temperature of 245° C. or even reach to 260° C. The belfry-like bumps 230 are metal with melting points higher than the above mentioned reflow temperature such as copper, gold, aluminum, etc. Therefore, the belfry-like bumps 230 can prevent cracks from spreading and increase the anchoring effects between the solder paste 250 and the belfry-like bumps 230 to achieve higher soldering reliability and to enhance POP product durability. Even under the thermal or mechanical stresses, cracks are formed at the soldering interfaces between the non-continuous sidewalls 233 of the belfry-like bumps 230 and the solder paste 250 but will cease spreading due to the first crack-restraining ring surfaces 231 so that the cracks will not spread along the inclined surfaces of the belfry-like bumps 230. Therefore, the electrical open issues of the micro contacts of POP can be avoided and the board-level reliability can be enhanced. Furthermore, the semiconductor packages 200 mentioned in this embodiment can be implemented in the normal non-stacking package products such as to replace the conventional window-type BGA packages or the fine-pitch BGA packages.

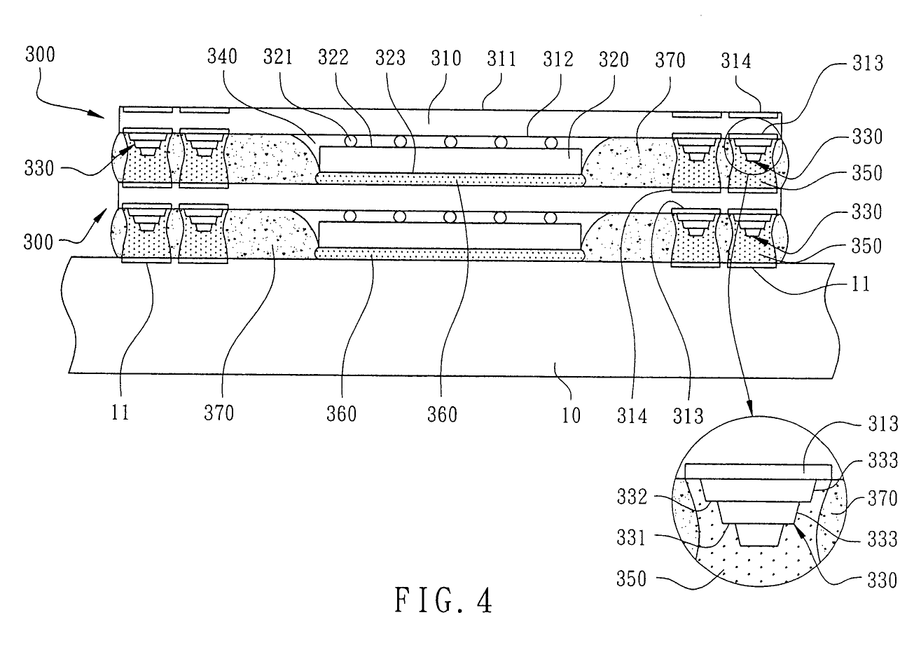

In the second embodiment of the present invention, as shown in FIG. 4, a plurality of semiconductor packages 300 are stacked together and surface-mounted on a printed circuit board 10. One of the semiconductor packages 300 primarily comprises a chip carrier 310, a chip 320, and a plurality of belfry-like bumps 330. The chip carrier 310 has a top surface 311 and a bottom surface 312 where a plurality of first conductive pads 313 are disposed on the bottom surface 312 and a plurality of second conductive pads 314 on the top surface 311 as stacking pads for stacking another semiconductor package 300.

In the present embodiment, the chip 320 has an active surface 322 and an opposing back surface 323 where the chip 320 has a plurality of bumps 321 disposed on the active surface 322. The chip 320 is disposed and electrically connected to the chip carrier 310 by the bumps 321. In the present embodiment, the chip 320 is disposed on the bottom surface 312 of the chip carrier 310 and the belfry-like bumps 320 are disposed at the peripheries of the chip 320 so that the top surface 311 of the chip carrier 310 is flat and will not damage the chip 320 nor the belfry-like bumps 330. Preferably, the back surface 323 of the chip 320 is exposed from the bottom surface 312 of the chip carrier 310 for better heat dissipation.

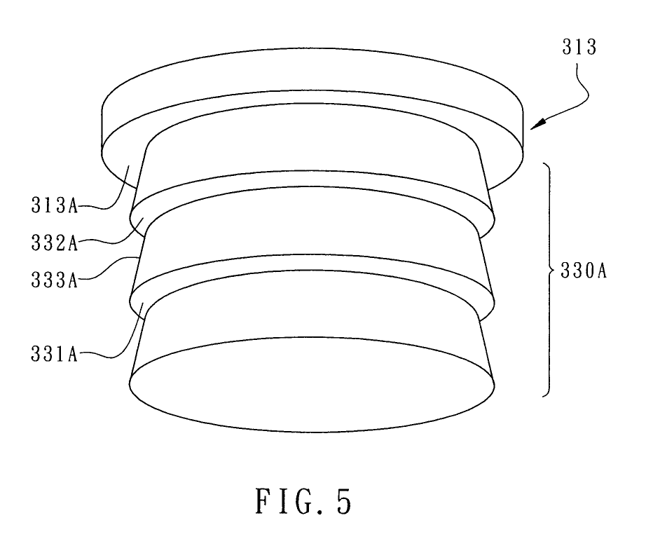

As shown in FIG. 4, the belfry-like bumps 330 are disposed on the corresponding first conductive pads 313 as external terminals and are soldered to the contact pads 11 of the printed circuit board 10 or to the second conductive pads 314 of another semiconductor package 300 stacked below by solder paste 350. The shapes of the belfry-like bumps 330 can be the same or different from the ones mentioned in the first embodiment. In one of the embodiments, the belfry-like bumps 330 are the same as the ones mentioned in the first embodiment. Each belfry-like bump 330 has at least a first crack-restraining ring surface 331 parallel to the corresponding first conductive pad 313 and between the top of the belfry-like bump 330 and the first conductive pad 313 to prevent the spreading of the soldering cracks. In the present embodiment, each crack-restraining ring surface 330 further has a second crack-restraining ring surface 332 disposed between the first crack-restraining ring surface 330 and the corresponding first conductive pad 313 and parallel to the first crack-restraining ring surface 331 without intersection. In the present embodiment, the inner diameter of the second crack-restraining ring surface 332 is larger than the one of the first crack-restraining ring surface 331 to form a plurality of non-continuous sidewalls 333. Therefore, when stacking a plurality of semiconductor packages 300, the first crack-restraining ring surfaces 331 and the second crack-restraining ring surfaces 332 can prevent the spreading of the soldering cracks. The solder paste 350 has a larger soldering area to enhance solder anchoring effects. Another belfry-like bumps 330A with different shapes are shown in FIG. 5, these are possible to replace the belfry-like bumps 330 mentioned above where the belfry-like bumps 330A are formed by a plurality of cones having a first crack-restraining ring surface 331A and at least a second crack-restraining ring surface 332A where the first crack-restraining ring surface 331A and the second crack-restraining ring surface 332A are parallel to the first conductive pads 313 and between the top of the belfry-like bumps 330A and the first conductive pads 313 to prevent the spreading of the soldering cracks. The second crack-restraining ring surface 332A is located between the first crack-restraining ring surface 331A and the corresponding first conductive pad 313 and parallel to the first crack-restraining ring surface 331A without intersection. In the present embodiment, the crack-restraining ring surfaces 331A and 332A have outer sharp edges so that the inner diameter of the second crack-restraining ring surface 332A is almost the same as the one of the first crack-restraining ring surface 331A to form a plurality of non-continuous sidewalls 333 to prevent the spreading of the soldering cracks and to achieve larger soldering areas and better soldering strengths.

As shown in FIG. 4 again, when a plurality of semiconductor packages 300 are stacking on a printed circuit board 10, preferably, each semiconductor package 300 further comprises a thermal-coupling component 360 such as thermal interface material (TIM) or heat dissipation grease formed on the exposed back surface 323 of the chip 320 and is thermal-coupled to the printed circuit board 10 or to the chip carrier 310 of the semiconductor package 300 stacked below for better heat dissipation. In a more detail embodiment, each semiconductor package 300 further comprises an encapsulant 370 such as under-filling materials formed on the bottom surface 312 of the chip carrier 310 to encapsulate the solder paste 350 and the chip 320 to avoid possible contaminations or electrical shorts by dust trapped in the POP spacing.

The above description of embodiments of this invention is intended to be illustrative and not limiting. Other embodiments of this invention will be obvious to those skilled in the art in view of the above disclosure.

What is claimed is:

1. A semiconductor package comprising:
a chip carrier having a top surface, a bottom surface and a plurality of first conductive pads on the bottom surface;
a chip disposed on and electrically connected to the chip carrier; and
a plurality of belfry-like bumps disposed on the corresponding first conductive pads as external terminals where each belfry-like bump has at least a first crack-restraining ring surface that is almost parallel to the first conductive pad and between the top of the belfry-like bump and the first conductive pad for preventing the spreading of soldering cracks.

2. The semiconductor package as claimed in claim 1, wherein each belfry-like bump further has a second crack-restraining ring surface located between the first crack-restraining ring surface and the first conductive pad and is almost parallel to the first crack-restraining ring surface without intersection.

3. The semiconductor package as claimed in claim 2, wherein the inner diameter of the second crack-restraining ring surface is greater than the one of the first crack-restraining ring surface.

4. The semiconductor package as claimed in claim 2, wherein the inner diameter of the second crack-restraining ring surface is approximately the same as the one of the first crack-restraining ring surface.

5. The semiconductor package as claimed in claim 1, wherein the first conductive pad has a peripheral surface exposed from the bottom of the belfry-like bump.

6. The semiconductor package as claimed in claim 1, further comprising solder paste soldering the belfry-like bumps and covering the first crack-restraining ring surfaces.

7. The semiconductor package as claimed in claim 5, further comprising solder paste soldering the belfry-like bumps and covering the first crack-restraining ring surfaces and the peripheral surfaces of the first conductive pads.

8. The semiconductor package as claimed in claim 1, wherein the chip carrier further has a plurality of second conductive pads disposed on the top surface for POP stacking.

9. The semiconductor package as claimed in claim 1, wherein the chip carrier is a printed circuit board.

10. The semiconductor package as claimed in claim 9, wherein the chip carrier has a wire-bonding slot for passing through a plurality of bonding wires to electrically connect the chip to the chip carrier.

11. The semiconductor package as claimed in claim 10, further comprising an encapsulant formed in the wire-bonding slot and extruded from the bottom surface to encapsulate the bonding wires.

12. The semiconductor package as claimed in claim 1, wherein an active surface of the chip is attached to the top surface of the chip carrier.

13. The semiconductor package as claimed in claim 12, wherein a back surface of the chip is exposed from the top surface of the chip carrier.

14. The semiconductor package as claimed in claim 1, wherein the chip is disposed on the bottom surface of the chip carrier with the belfry-like bumps disposed at the peripheries of the chip.

15. The semiconductor package as claimed in claim 14, wherein a back surface of the chip is exposed from the bottom surface of the chip carrier.

16. The semiconductor package as claimed in claim 15, further comprising a thermal-coupling component disposed on the exposed back surface of the chip.

17. The semiconductor package as claimed in claim 14, further comprising an encapsulant formed on the bottom surface of the chip carrier.

18. The semiconductor package as claimed in claim 1, wherein the crack-restraining ring surfaces have outer sharp edges.
